(19) United States
(12) Patent Application Publication
(10) Pub. No.: US 2018/0062655 A1
(43) Pub. Date: Mar. 1, 2018

(54) Level-Shifter with Defined Power-up State and Increased Density

(71) Applicant: QUALCOMM Incorporated, San Diego, CA (US)

(72) Inventors: Dongmin Park, San Diego, CA (US); Jong Min Park, San Diego, CA (US); Lai Kan Leung, San Marcos, CA (US)

(21) Appl. No.: 15/253,683

(22) Filed: Aug. 31, 2016

(51) Int. Cl. H03K 19/0185

(52) U.S. Cl. CPC H03K 19/018507

(57) ABSTRACT

A level-shifter is provided in which the devices may all be sized approximately the same yet a known startup state is provided at power-up by forming the level-shifter using a one-sided NMOS latch. The one-sided NMOS latch is powered through a pair of head-switch transistors. A pair of pull-down transistors function to flip a binary state for the one-sided NMOS latch.

### TECHNICAL FIELD

This application relates generally to level-shifters, and more particularly to level-shifters with a defined power-up state and increased density.

### BACKGROUND

A level shifter conventionally includes a latch formed by two-cross-coupled inverters. For example, level-shifter 100 shown in FIG. 1 includes a first inverter 115 formed by a serial stack of a PMOS transistor P1 and an NMOS transistor M2 that is cross-coupled with a second inverter 120 formed by another serial stack of a PMOS transistor P2 and an NMOS transistor M3. The drains of transistors P2 and M3 form a true output node (OUT) for level-shifter 100. Similarly, the drains of transistors P1 and M2 form a complement output node (OUTB). Cross-coupled inverters 115 and 120 are located within an input output (I/O) power domain powered by an I/O power supply voltage (VDDIO) that is greater than a core power supply voltage (VDD) that powers a pair of input inverters 105 and 110. Inverter 105 inverts a true input signal into a complement input signal (INB) that drives a gate of a pull-down NMOS transistor M4 coupled between the output node and ground. Inverter 110 inverts the complement input signal back into the true input signal to drive a gate of a pull-down NMOS transistor M1 coupled between the complement output node and ground. Depending upon the state of the true input signal, one of the pull-down transistors M1 and M4 switches on to ground the corresponding one of the true and complement output nodes. Due to the feedback through the cross-coupled inverters 115 and 120, the non-grounded one of the true and complement output nodes is then charged to the I/O power supply voltage. The true input signal is thus level-shifted from the core power supply voltage to the I/O power supply voltage.

Note that the pull-down transistors M1 and M4 must be relatively large so that they can change the state of the latch formed by cross-coupled inverters 115 and 120. For example, if the state of this latch was such that the complement output node was charged to the I/O power supply voltage, the PMOS transistor P1 was switched on. To flip the state of the latch such that the true output node is instead charged to the I/O power supply voltage requires the pull-down transistor M1 to discharge the complement output node despite the PMOS transistor P1 initially being on and continuing to charge this node. A similar struggle occurs between pull-down transistor M4 and PMOS transistor P2 when flipping the latch from storing a logical one to storing a logical zero (the true output node transitioning from charged to the I/O power supply voltage to being discharged). Making the pull-down transistors M1 and M4 relatively large compared to either of the inverter transistors M2 and M3 (and thus in turn to either of the inverter transistors P1 and P2) allows the struggle to be completed relatively quickly so that level-shifter 100 may have high-speed operation.

A similar difference in transistor size ensures that level-shifter 100 has a known state at power-up. In particular, at power-up both the true input signal and its complement will be grounded such that both pull-down transistors M1 and M4 are off. The true output node and the complement output nodes for level-shifter 100 will also be grounded such that the inverter transistors M2 and M3 are also off. As the I/O power supply rises, both inverter transistors P1 and P2 will thus be initially on such that they charge their drains to cause the true output node and the complement output node to rise in voltage. Without any asymmetry for inverters 115 and 120, it would then be unpredictable which inverter transistor M2 and M3 would react more strongly to the charging of the true and complement output nodes by switching on. Such a random state for level-shifter 100 at power-up is undesirable and can lead to glitches or other errors. To ensure a known state at power-up, one of the inverter transistors is made larger than the other. For example, inverter transistor M3 may be made several times larger than inverter transistor M2. Inverter transistor M3 will thus react to the charging of the complement output node at power-up by switching on more strongly than inverter transistor M2. Inverter transistor M3 will thus discharge the true output node. This discharge reinforces the charging of the complement output node such that level-shifter 100 will reliably output a binary zero at power-up. To further reinforce this known state, transistor P1 may be larger than transistor P2.

Although this asymmetry for the pull-down transistors and the latch provides a known start-up condition and enables high-speed operation, it lowers density for level-shifter 100. Accordingly, there is a need in the art for level-shifters having a known start-up state and high-speed operation with improved density.

### SUMMARY

To provide a known startup state, a level-shifter is provided with a one-sided NMOS latch that includes an inverter having an inverter PMOS transistor cross-coupled with a non-inverter PMOS transistor. As implied by the name, a one-sided NMOS latch includes only one inverter NMOS transistor. A drain of the non-inverter PMOS transistor thus couples to ground only through a first pull-down NMOS transistor. A drain of the inverter PMOS transistor couples to ground through a second pull-down NMOS transistor and also through the inverter NMOS transistor.

A first power domain powered by a first power supply voltage provides a true input signal and a complement of the true input signal to the level-shifter. A source of the non-inverter PMOS transistor couples through a first head-switch PMOS transistor to a power supply node providing a second power supply voltage for a second power domain. Similarly, a source of the inverter PMOS transistor couples through a second head-switch PMOS transistor to the power supply node. A drain of the non-inverter PMOS transistor drives the input of the inverter. Thus, the drain of the non-inverter PMOS transistor couples to a gate for the inverter PMOS transistor and to a gate for the inverter NMOS transistor. The source of the inverter NMOS transistor couples to ground whereas a drain for the inverter NMOS transistor couples to a drain of the inverter PMOS transistor. The output of the inverter drives the gate of the non-inverter PMOS transistor. The drain for the inverter PMOS transistor (and the drain for the inverter NMOS transistor) thus couples to the gate of the non-inverter PMOS transistor. An input signal (either the true input signal or its complement) drives a gate of the first pull-down transistor and a gate for the first head-switch transistor. A remaining input signal (the remaining one of the true input signal and its complement) drives a gate of the second pull-down transistor and a gate for the second head-switch transistor.

The exclusion of a second inverter in the one-sided NMOS latch ensures a known startup state for the level-shifter. In particular, both the true input signal and its complement will be grounded at power-up such that both the first head-switch transistor and the second head-switch transistor are conducting at power-up. Similarly, both the inverter PMOS transistor and the non-inverter PMOS transistor are conducting at power-up such that the drain for the inverter PMOS transistor and the drain for the non-inverter PMOS transistor both begin to charge towards the second power supply voltage. Due to the cross-coupling of the drain for the non-inverter PMOS transistor to the gate of the inverter NMOS transistor, the inverter NMOS transistor thus begins to switch on and discharge the inverter output. This discharge of the inverter output reinforces the switching on of the non-inverter PMOS transistor. The drain of the non-inverter PMOS transistor, which forms one of a true output node or a complement output node for the level-shifter, is thus reliably charged to the second power supply voltage at startup. Similarly, the drain of the inverter PMOS transistor, which forms a remaining one of the true or complement output nodes for the level-shifter, is reliably discharged at startup.

This known startup state is achieved without requiring any device asymmetry, which advantageously increases density as each transistor in the one-sided NMOS latch may be sized at the minimum-required size for whatever process node is used to manufacture the level-shifter. Moreover, the first and second pull-down transistors may also be sized at this minimum-required size since the struggle with regard to flipping a state of the one-sided NMOS latch is relieved through the first and second head-switch transistors. For example, suppose that the binary state of the one-sided NMIOS latch was such that the drain of the non-inverter PMOS transistor had been charged to the second power supply voltage and that the true input signal driving the gate of the first-pull down transistor and the gate of the first head-switch transistor is asserted to the first power supply voltage. The first head-switch transistor will be weakly switched off, which weakens the non-inverter PMOS transistor. The first pull-down transistor can then quickly discharge the drain of the non-inverter PMOS transistor despite the first pull-down transistor have the same approximate dimensions (channel length and width) as the non-inverter PMOS transistor.

These and additional advantages may be better appreciated through the following detailed description.

### BRIEF DESCRIPTION OF THE DRAWINGS

FIG. 1 is a circuit diagram of a conventional level-shifter.

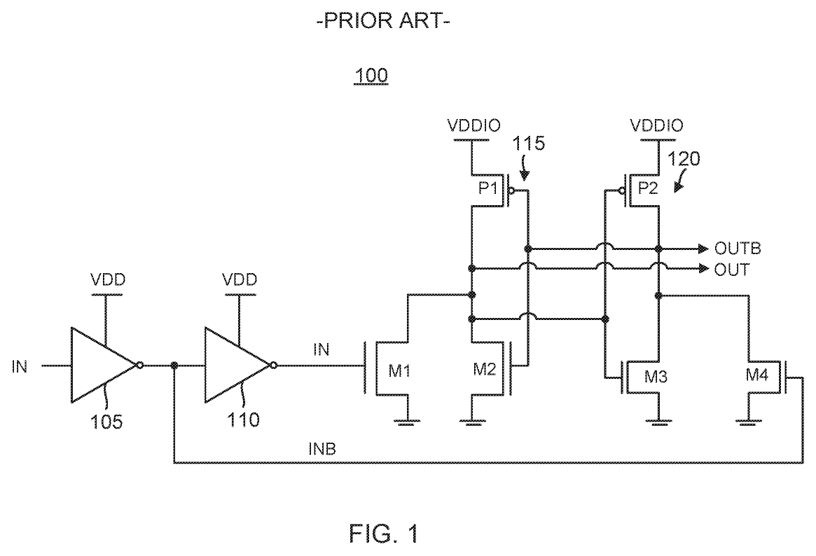

FIG. 2 is a circuit diagram of a level-shifter in accordance with an aspect of the disclosure.

FIG. 3 is a flowchart for a method of operation of a level-shifter in accordance with an aspect of the disclosure.

These aspects of the disclosure and their advantages are best understood by referring to the detailed description that follows. It should be appreciated that like reference numerals are used to identify like elements illustrated in one or more of the figures.

### DETAILED DESCRIPTION

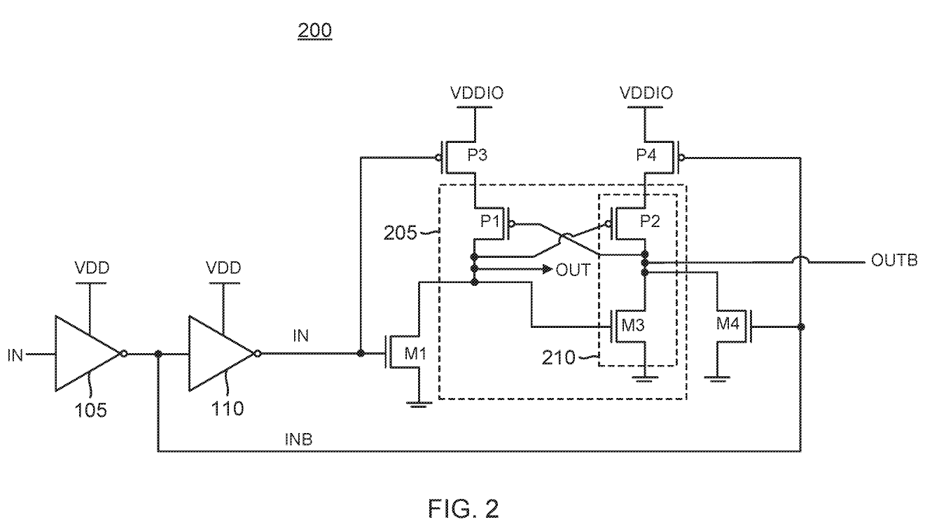

A level-shifter 200 is provided as shown in FIG. 2 that offers increased density and a known start-up state. A true input signal (IN) is generated in a first power domain powered by a first power supply voltage. The following discussion will assume that the first power domain is a core power domain powered by a core power supply voltage (VDD) but it will be appreciated that level-shifter 200 may also be used to level-shift from one peripheral power supply voltage to another. Inverters 105 and 110 function within the core power domain as discussed with regard to level-shifter 100. Thus, the true input signal (IN) drives inverter 105 powered by the core power supply voltage VDD to be inverted into the complement input signal (INB). Inverter 110 is also powered by the core power supply voltage VDD and inverts the complement input signal back into the true input signal. A one-sided NMOS latch 205 latches an output signal carried on a true output node (OUT) and a complement output signal carried on a complement output node (OUTB) responsive to the binary states of the true input signal and the complement input signal.

One-sided NMOS latch 205 is denoted as being “one-sided” because it contains only one inverter 210. Inverter 210 includes an inverter PMOS transistor P2 having a drain coupled to a drain of an inverter NMOS transistor M3. The source of inverter transistor M3 couples to ground. The output of inverter 210 (the drains of inverter transistors P2 and M3) forms the true output node OUT and also couples to a gate of a non-inverter PMOS transistor P1. The drain of non-inverter transistor P1 couples to the gates of inverter transistors P2 and M3 and also forms the complement output node OUTB. One-sided latch 205 is powered through a pair of head-switch transistors in a second power domain such as a input/output (VDDIO) power domain. In particular, the source of non-inverter transistor P1 couples to a drain of a first head-switch PMOS transistor P3 having a source tied to a VDDIO power supply node supplying the VDDIO power supply voltage, which is greater than the core power supply voltage VDD. Similarly, the source of inverter transistor P2 couples to a drain of a second head-switch PMOS transistor P4 having a source also tied to the VDDIO power supply node.

The true input signal drives a gate of first pull-down NMOS transistor M1 having a source coupled to ground and drain coupled to the complement output node (drain of non-inverter transistor P3). Note that first pull-down NMOS transistor M1 is the only path to ground for discharging the complement output node since non-inverter transistor P1 is not included into any inverter such as inverter 115 discussed with regard to level-shifter 100. The true input signal carried on a true input signal node also drives a gate of first head-switch transistor P3. Note that it is arbitrary to denote the drain of non-inverter transistor P1 as the complement output node. In an alternative embodiment, the drain of non-inverter transistor P1 may form the true output node. In that case, it would be the complement input signal that would drive the gate of first pull-down transistor M1 and first head-switch transistor P3.

The complement input signal (INB) carried on a complement input signal node drives a gate of second pull-down NMOS transistor M4 having a source coupled to ground and a drain coupled to the complement output node (the drain of inverter transistor P1 and the drain of inverter transistor M3). In contrast to the complement output node, the true output node thus has two paths to ground: one through inverter transistor M3 and one through second pull-down transistor M4. The complement input signal also drives a gate of second head-switch transistor P4. It is also arbitrary to denote the drain of inverter transistor P2 as the true output node. In an alternative embodiment, the drain of inverter transistor P2 may form the complement output node. In such an embodiment, it would then be the true input signal that would drive the gates of the second pull-down transistor M4 and the second head-switch transistor P4.

At the initiation of power-up, both the true input signal and its complement are grounded such that the first pull-down transistor M1 and the second pull-down transistor M4 are both off. The true output signal and its complement are also grounded such that both the non-inverter transistor P1 and the inverter transistor P2 are conducting. The grounded state for the true input signal and its complement also means that the first head-switch transistor P3 and the second head-switch transistor P4 are conducting. The power supply (not illustrated) charging the VDDIO power supply voltage will thus cause the drains of the non-inverter transistor P1 and the inverter transistor P2 to rise in voltage in response to the initiation of the power-up of level-shifter 200. Since the drain of non-inverter transistor P1 is cross-coupled to the gate of inverter transistor M3, this rise in voltage causes inverter transistor M3 to switch on and discharge the true output node (the drain of inverter transistor P2). Given that the true output node is cross-coupled to the gate of non-inverter transistor P1, the discharge of the true output node reinforces the on-state of non-inverter transistor P1 such that the complement output node quickly charges to its startup state of being charged to the VDDIO power supply voltage. Similarly, the true output node is discharged to a startup state of being grounded. These known start-up states are achieved without requiring any asymmetry in the devices for level-shifter 100. Transistors P1, P3, P4, P2, and M3 may thus all be the minimum size required for whatever process node is used to manufacture level-shifter 100. In this fashion, density is markedly improved over level-shifter 100.

After power-up, level-shifter 200 is ready to receive the input signals. If the true input signal is asserted to the core power supply voltage VDD, the first pull-down transistor M1 is switched on to discharge the complement output node. Although non-inverter P1 transistor had been conducting at start-up, it will not struggle with this discharge since it is weakened through the assertion of the true input signal weakly shutting off the first head-switch transistor P3. With first head-switch transistor P3 being weakly off, non-inverter transistor P1 is starved of charge, which allows first pull-down transistor M1 to be sized approximately the same (same channel width and length) as used for the devices in one-sided latch 205. The discharge of the complement output node causes inverter transistor P2 to conduct so that the true output node is charged to the JO power supply voltage VDDIO. The true input that was charged to the core power supply voltage VDD is thus level-shifted to the true output signal that is charged to the 10 power supply voltage VDDIO.

Similarly, if the true input signal is then grounded, the complement input signal is asserted to the core power supply voltage VDD. This assertion of the core power supply voltage VDD causes second pull-down transistor M4 to discharge the true output node. This discharge does not struggle with inverter PMOS transistor P2 since the assertion of the complement input signal weakly shuts off second head-switch transistor P4 to starve inverter PMOS transistor P2 of charge. The first pull-down transistor M1 and the second pull-down transistor M4 may thus be sized approximately the same as the devices in one-sided latch 205. Moreover, the first head-switch transistor P3 and the second head-switch transistor P4 may also be manufactured at the minimum size required for whatever process node is used to manufacture level-shifter 200. Density is thus greatly enhanced as compared to level-shifter 100 without sacrificing any speed of operation. In one embodiment, head-switch transistors P3 and P4 may be deemed to form a means for selectively isolating the non-inverter PMOS transistor from a power supply node for a second power domain responsive to an assertion of the first input signal and for selectively isolating the inverter PMOS transistor from the power supply node responsive to an assertion of the second input signal. A method of operation for a level-shifter in accordance with an aspect of the disclosure will now be discussed.

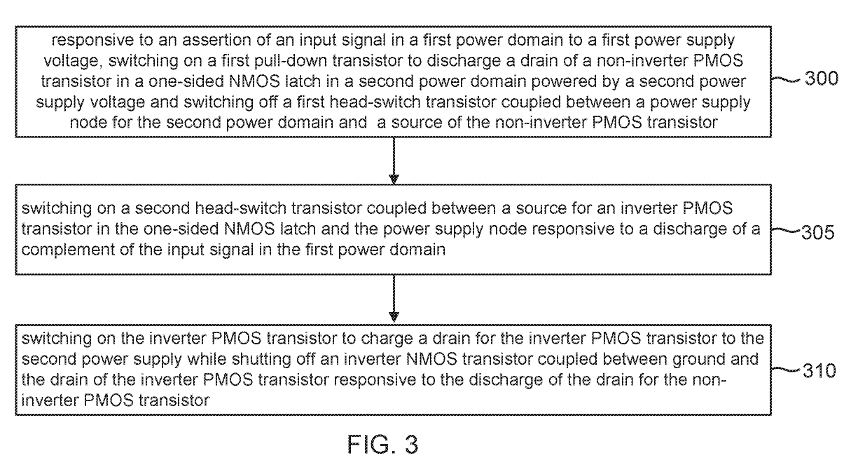

FIG. 3 is a flowchart for a level-shifting method of operation. The method includes an act 300 of, responsive to an assertion of an input signal in a first power domain to a first power supply voltage, switching on a first pull-down transistor to discharge a drain of a non-inverter PMOS transistor in a one-sided NMOS latch in a second power domain powered by a second power supply voltage and switching off a first head-switch transistor coupled between a power supply node for the second power domain and a source of the second PMOS transistor. An example of act 300 is the assertion of the true input signal so as to discharge the drain of non-inverter transistor P1 while switching off first head-switch transistor P3. However, it will be appreciated that act 300 could be responsive to an assertion of the complement input signal in alternative embodiments.

The method also include an act 305 of switching on a second head-switch transistor coupled between a source for an inverter PMOS transistor in the one-sided NMOS latch and the power supply node responsive to a discharge of a complement of the input signal in the first power domain. The switching on of second head-switch transistor P4 responsive to the discharge of the complement input signal (and thus the discharge of the complement input signal node) is an example of act 305.

Finally, the method includes an act 310 of switching on the inverter PMOS transistor to charge a drain for the inverter PMOS transistor to the second power supply while shutting off an inverter NMOS transistor coupled between ground and the drain of the inverter PMOS transistor responsive to the discharge of the drain for the non-inverter PMOS transistor. The switching on of inverter transistor P2 while switching off inverter transistor M3 responsive to the discharge of the complement output node is an example of act 310.

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

What is claimed is:

1. A level-shifter, comprising:
an inverter PMOS transistor;
an inverter NMOS transistor having a drain coupled to the a drain of the inverter PMOS transistor,
a non-inverter PMOS transistor having a drain coupled to a gate for the inverter PMOS transistor and to a gate for the inverter NMOS transistor, wherein the drain of the inverter PMOS transistor is coupled to a gate for the non-inverter PMOS transistor;
a first pull-down transistor coupled between a drain of the non-inverter PMOS transistor and ground, wherein a gate for the first pull-down transistor is coupled to a first input signal node carrying an input signal from a first power domain powered by a first power supply voltage; and
a first head-switch transistor coupled between a source of the non-inverter PMOS transistor and a power supply node configured to supply a second power supply voltage for a second power domain, the second power supply voltage being greater than the first power supply voltage, wherein a gate for the first head-switch transistor is coupled to the input signal node.

2. The level-shifter of claim 1, further comprising a second pull-down transistor coupled between a drain of the inverter PMOS transistor and ground, wherein a gate for the second pull-down transistor is coupled to a complement input signal node carrying a complement of the input signal.

3. The level-shifter of claim 2, further comprising a second head-switch transistor coupled between a source of the inverter PMOS transistor and the power supply node, and wherein a gate of the second head-switch transistor is coupled to the complement input signal node.

4. The level-shifter of claim 3, wherein the input signal is a true input signal and the drain of the inverter PMOS transistor is an output node for a level-shifted version of the true input signal.

5. The level-shifter of claim 3, wherein the input signal is a complement input signal and the drain of the inverter PMOS transistor is an output node for a level-shifted version of the complement input signal.

6. The level-shifter of claim 3, wherein the first head-switch transistor and the second head-switch transistor are both PMOS transistors.

7. The level-shifter of claim 3, wherein the first pull-down transistor and the second pull-down transistor are both NMOS transistors.

8. The level-shifter of claim 1, wherein the inverter PMOS transistor, the inverter NMOS transistor, the non-inverter PMOS transistor, the first pull-down transistor, and the first head-switch transistor all have approximately the same dimensions.

9. The level-shifter of claim 3, further comprising:
a first inverter in the first power domain configured to invert the input signal into the complement of the input signal, and
a second inverter in the first power domain configured to invert the complement of the input signal back into the input signal, wherein an output node for the second inverter comprises the first input signal node.

10. The level-shifter of claim 9, wherein an output node for the first inverter comprises the complement input signal node.

11. A level-shifting method, comprising
responsive to an assertion of an input signal in a first power domain to a first power supply voltage, switching on a first pull-down transistor to discharge a drain of a non-inverter PMOS transistor in a one-sided NMOS latch in a second power domain powered by a second power supply voltage and switching off a first head-switch transistor coupled between a power supply node for the second power domain and a source of the non-inverter PMOS transistor;
switching on a second head-switch transistor coupled between a source for an inverter PMOS transistor in the one-sided NMOS latch and the power supply node responsive to a discharge of a complement of the input signal in the first power domain; and
switching on the inverter PMOS transistor to charge a drain for the inverter PMOS transistor to the second power supply while shutting off an inverter NMOS transistor coupled between ground and the drain of the inverter PMOS transistor responsive to the discharge of the drain for the non-inverter PMOS transistor.

12. The method of claim 11, wherein the second power supply voltage is greater than the first power supply voltage.

13. The method of claim 12, wherein the first power domain is a core power domain and wherein the second power domain is an input/output (I/O power domain.

14. The method of claim 11, further comprising:
responsive to an assertion of the complement the input signal to the first power supply voltage, switching on a second pull-down transistor coupled between the drain of the inverter PMOS transistor and ground while switching off the second head-switch transistor to discharge the drain of the inverter PMOS transistor to ground;
switching on the first head-switch transistor while switching off the first pull-down transistor responsive to a discharge of the input signal; and
switching on the non-inverter PMOS transistor to charge the drain of the non-inverter PMOS transistor to the second power supply voltage responsive to the discharge of the drain of the inverter PMOS transistor.

15. The method of claim 11, wherein the assertion of the input signal is an assertion of a true input signal, the method further comprising inverting the asserted true input signal to form the complement of the input signal.

16. The method of claim 11, wherein the assertion of the input signal is an assertion of a complement input signal, the method further comprising inverting the asserted complement input signal to form the complement of the input signal.

17. The method of claim 11, further comprising:
during a power-up of the one-sided NMOS latch, switching on the inverter NMOS transistor to force the one-sided NMOS latch into a known power-up state.

18. A level-shifter, comprising:
a one-sided NMOS latch having a latch inverter cross-coupled with a non-inverter PMOS transistor,
a first pull-down transistor coupled between a drain of the non-inverter PMOS transistor and ground, wherein a gate for the first pull-down transistor is configured to receive a first input signal from a first power domain;
a second pull-down transistor coupled between a drain of an inverter PMOS transistor in the latch inverter and ground, wherein a gate for the second pull-down transistor is configured to receive a second input signal from the first power domain, the second input signal being the complement of the first input signal and
means for selectively isolating the non-inverter PMOS transistor from a power supply node for a second power domain responsive to an assertion of the first input signal and for selectively isolating the inverter PMOS transistor from the power supply node responsive to an assertion of the second input signal.

19. The level-shifter of claim 18, wherein the first power domain is core power domain and the second power domain is an input/output (I/O) power domain.

20. The level-shifter of claim 18, wherein the first input signal is a true input signal and the second input signal is a complement input signal.
